(19) United States
(12) Patent Application Publication
(10) Pub. No.: US 2008/0087220 A1
(43) Pub. Date: Apr. 17, 2008

(54) Plasma Processing Apparatus and Multi-Chamber System

(75) Inventor: Toshiaki Fujisato, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/581,522

(22) PCT Filed: Dec. 2, 2004
(86) PCT No.: PCT/JP04/17932

§ 371 Date: Feb. 13, 2007

(30) Foreign Application Priority Data
Dec. 3, 2003 (JP) 2003-403950

(51) Int. Cl. C23C 16/00

(52) U.S. Cl. 118/719; 118/723 R

(57) ABSTRACT

A susceptor (16) on which a predetermined target wafer (W) is mounted, and a support table (15) for supporting the susceptor (16) are provided at generally the center in a chamber (2). A process gas supply device (4) supplies a process gas for processing the wafer (W) into the chamber (2). A first high-frequency power source (5) and a second high-frequency power source (7) generate plasma of the supplied process gas by applying predetermined high-frequency voltages respectively, and process the wafer (W). A dike (18) having a grounded conductive member (18a) is provided around the support table (15) and the susceptor (16), and the generated plasma is thereby confined in the area above the wafer (W) mounted on the susceptor (16).

### TECHNICAL FIELD

The present invention relates to a plasma processing apparatus and a multi-chamber system having the same.

### BACKGROUND ART

A plasma processing apparatus, for example, a plasma CVD (Chemical Vapor Deposition) apparatus supplies a process gas into a chamber for loading a process target, for example, a semiconductor wafer, generates a plasma in the chamber by applying a predetermined high-frequency voltage, and applies a predetermined process on the semiconductor wafer by the plasma.

The chamber wall of the plasma CVD apparatus has a stable potential and a low impedance. Therefore, the plasma is likely to be generated with the chamber wall present near a mounting table on which the semiconductor wafer is mounted serving as an opposite electrode. This makes it difficult for the plasma generated in the chamber to be concentrated in the process area between a showerhead, from which the process gas is blown, and the mounting table on which the semiconductor wafer is mounted.

In a case where the plasma is not concentrated in the process area, there exists much plasma that does not work on the semiconductor wafer, and therefore a problem arises that the plasma processing efficiency becomes poor. There also arises a problem that the quality, the film thickness, etc. of the film to be formed on the semiconductor wafer are likely to be uneven.

Hence, for example, according to Patent Literature 1, the mounting table is circumferentially surrounded with a thin dielectric material, in order to prevent the plasma from going and extending considerably beyond the neighborhood of the semiconductor wafer mounted on the mounting table.

Patent Literature 1: National Publication No. 2001-516948

### DISCLOSURE OF INVENTION

### Problem to be Solved by the Invention

However, the above-described thin dielectric material merely prevents the plasma from going and extending considerably beyond the neighborhood of the semiconductor wafer, thus cannot sufficiently prevent the plasma from spreading beyond the above-described process area. Therefore, there has still been arising the problem that the plasma processing efficiency is poor and the quality, the film thickness, etc. of the film formed on the semiconductor wafer are likely to be uneven.

The present invention was made in view of the above-described problems, and an object of the present invention is to provide a plasma processing apparatus which realizes an efficient plasma process, and a multi-chamber system having the same.

Another object of the present invention is to provide a plasma processing apparatus which confines the plasma in the area above the process target placed in the chamber, and a multi-chamber system having the same.

### Means for Solving the Problems

To achieve the above objects, a plasma processing apparatus of the present invention is a plasma processing apparatus for applying a plasma process to a process target, and comprises: a process chamber for applying a plasma process to the process target; a mounting table, provided in the process chamber, for mounting thereon the process target; a process gas supply unit for supplying a process gas for applying the plasma process to the process target into the process chamber; a plasma generation unit for generating plasma of the process gas supplied by the process gas supply unit by applying a high-frequency voltage; and a dike for confining the plasma generated by the plasma generation unit in an area above the process target mounted on the mounting table, wherein the dike comprises a conductive member formed of a conductor, and the conductive member is grounded.

The dike may comprise the conductive member formed of a conductor and an insulating member which covers the conductive member and electrically insulates between the conductive member and the mounting table.

The dike may comprise a protruding portion which is formed to be higher than the process target mounted on the mounting table, so as to surround the area above the process target.

An interval between a top end of the dike and an inner wall of the process chamber may be 85 mm or smaller.

The interval may preferably be 30 mm or smaller, further preferably, 25 mm or smaller.

The plasma processing apparatus may further comprise a lifting unit for lifting up or down the dike in the process chamber.

The plasma processing apparatus may further comprise a lifting unit for lifting up or down the dike and the mounting table in the process chamber.

To achieve the above objects, a multi-chamber system according to the Present invention is characterized in that the above-described plasma processing apparatus is provided in at least one chamber.

### EFFECTS OF THE INVENTION

According to the present invention, it is possible to confine the plasma in the area above the wafer placed in the chamber, and to realize an efficient plasma process.

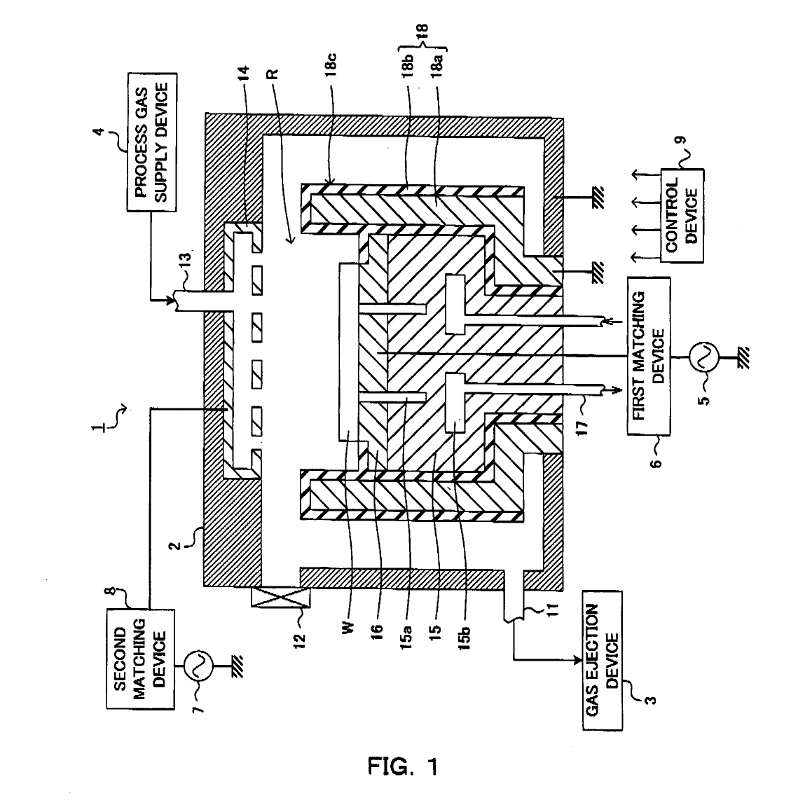

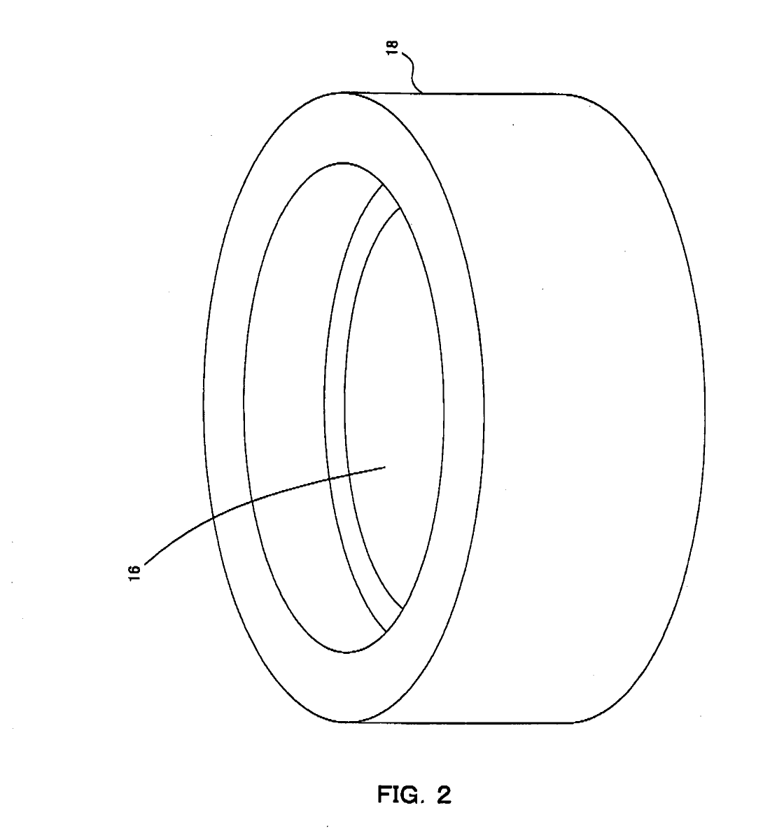

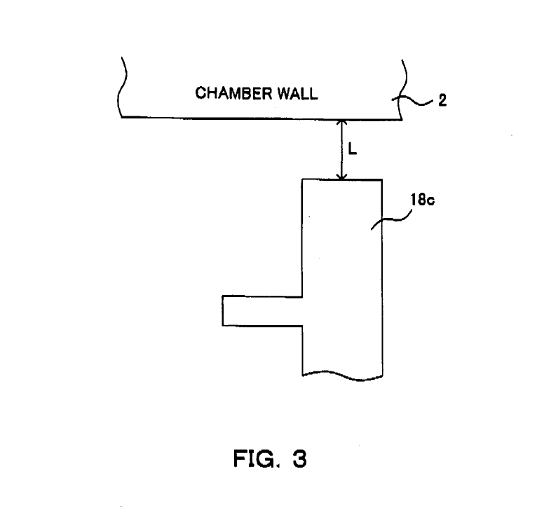

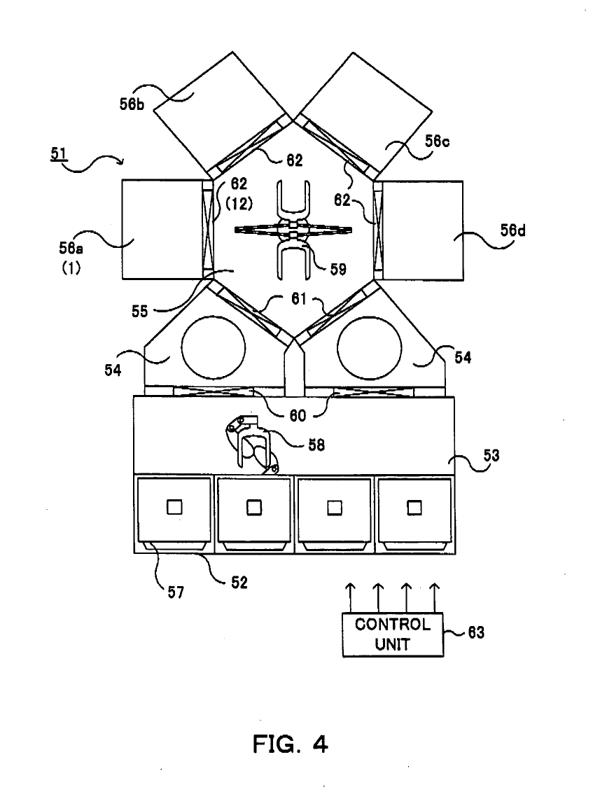

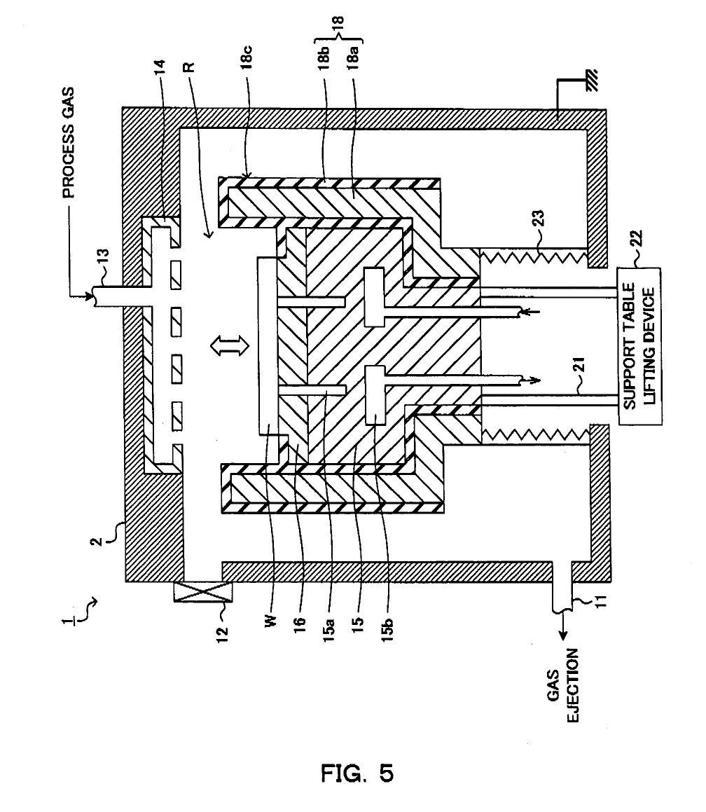

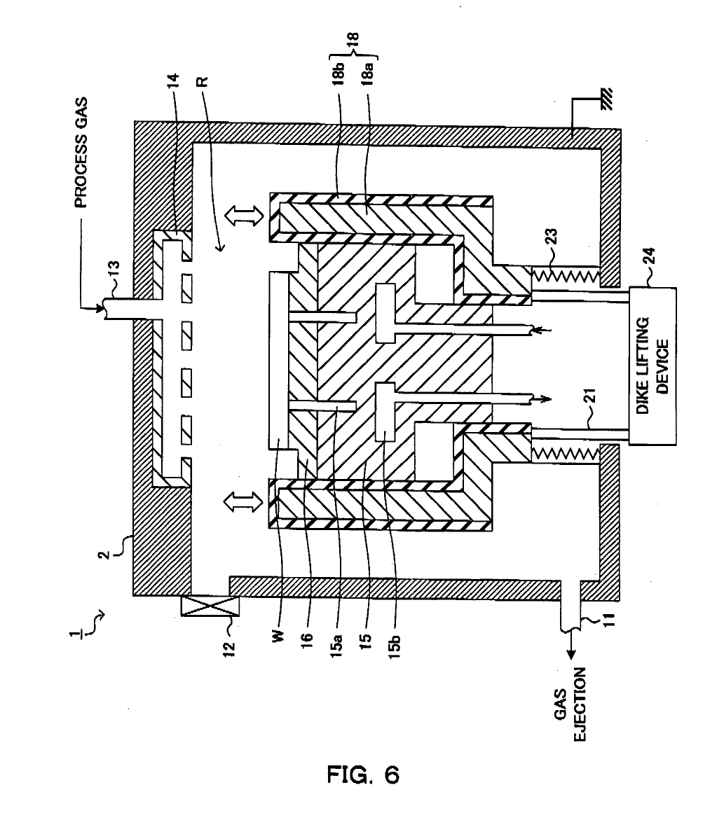

### BRIEF DESCRIPTION OF DRAWINGS

[FIG. 1] It is a diagram showing a structure of a plasma processing apparatus according to an embodiment of the present invention.

[FIG. 2] It is a perspective diagram of a dike constituting the plasma processing apparatus of FIG. 1.

[FIG. 3] It is a diagram showing an interval between the dike and a chamber constituting the plasma processing apparatus of FIG. 1.

[FIG. 4] It is a diagram showing a structure of a multi-chamber system according to an embodiment of the present invention.

[FIG. 5] It is a diagram showing another structure of the plasma processing apparatus according to an embodiment of the present invention.

[FIG. 6] It is a diagram showing another structure of a plasma processing apparatus according to an embodiment of the present invention.

### EXPLANATION OF REFERENCE NUMERALS

1 plasma processing apparatus

2 chamber

3 gas ejection device

4 process gas supply device

5 first high-frequency power source

6 first matching device

7 second high-frequency power source

8 second matching device

9 control device

11 gas ejection tube

12 gate valve

13 gas supply tube

14 showerhead

15 support table

15a lift pins

15b flowpath

16 susceptor

17 refrigerant supply tube

18 dike

18a conductive member

18b covering member

21 shaft

22 support table lifting device

23 bellows

24 dike lifting device

51 multi-chamber system

56 chamber

63 control unit

### BEST MODE FOR CARRYING OUT THE INVENTION

A plasma processing apparatus according to the present invention and a multi-chamber system comprising the plasma processing apparatus will be explained below. The following explanation will be made by employing a plasma CVD (Chemical Vapor Deposition) apparatus as an example of the plasma processing apparatus.

FIG. 1 is a diagram showing the structure of the plasma processing apparatus according to an embodiment of the present invention.

As shown in FIG. 1, the plasma processing apparatus 1 according to an embodiment of the present invention comprises a chamber 2, a gas ejection device 3, a process gas supply device 4, a first high-frequency power source 5, a first matching device 6, a second high-frequency power source 7, a second matching device 8, and a control device 9.

The chamber 2 is formed of a conductive material, for example, formed of aluminum subjected to almite treatment (anodizing) or the like. The chamber 2 is grounded.

A gas ejection tube 11 for ejecting gas in the chamber 2 and a gate valve 12 for a wafer (semiconductor wafer) W as the process target to be carried in or out, are provided at the side wall of the chamber 2. Carrying in or out of the wafer W is performed between a later-described load lock chamber which joins with the chamber 2, while the gate valve 12 is opened.

A process gas supply tube 13 for introducing a process gas into the chamber 2, and a showerhead 14 which is connected to the process gas supply tube 13 to serve as a supply opening for the process gas supplied through the process gas supply tube 13 are provided on the top of the chamber 2. The showerhead 14 is formed of a hollow aluminum or the like having multiple holes in its bottom. The showerhead 14 spreads the process gas from the process gas supply tube 13 to supply it to the entire surface of the wafer W uniformly, and also serves as an upper electrode.

A support table 15 is set at generally the center of the bottom of the chamber 2. A susceptor 16 to serve as a mounting table on which the wafer W is mounted and to serve as a lower electrode is set on the support table 15. The susceptor 16 is set to be opposite to the showerhead 14 serving as the upper electrode.

A plurality of lift pins 15a, which are lifted up or down by an unillustrated lifting mechanism are provided inside the support table 15. The wafer W carried into the chamber 2 is mounted on the lift pins 15a being lifted up, and is mounted on the susceptor 16 as the lift pins 15a are lifted down. Further, the wafer W subjected to a plasma process is separated from the susceptor 16 as the lift pins 15a are lifted up. The length of the lift pins 15a is set such that the wafer W can be lifted to a higher position than a later-described dike 18, when the wafer W is carried in or out.

A flow path 15b for circulating a refrigerant such as Fluorinert™ or the like is formed inside the support table 15. The flow path 15b is connected to an unillustrated refrigerant supply device through a refrigerant supply tube 17. As the refrigerant supplied from the refrigerant supply device circulates through the flow path 15b, the temperature of the susceptor 16 and wafer W mounted on the susceptor 16 is controlled to a predetermined temperature.

A dike 18 as shown in FIG. 2, which surrounds the support table 15 and the susceptor 16 are provided around the support table 15 and the susceptor 16. The dike 18 has a protruding portion 18c, which is formed to be higher than the wafer W mounted on the susceptor 16, so as to surround the area above the wafer W. i.e., a process area R between the wafer W (or the susceptor 16) mounted on the susceptor 16 and the showerhead 14. The dike 18 is provided in order to confine plasma generated in the chamber 2 in the process area R.

The cross-sectional shape and height of the protruding portion 18c (the portion protruding from the surface of the susceptor 16) of the dike 18 are set so as to be capable of substantially confusing plasma in the aforementioned process area R. In other words, the cross-sectional shape and height of the protruding portion 18c are set such that any influence upon the process of the wafer W, that may be given by plasma spreading outside the aforementioned process area R, can be ignored.

Such cross-sectional shape and height of the protruding portion 18c are determined beforehand by theoretical calculations or experiments, etc. For example, that the interval L between the top end of the protruding portion 18c and the inner wall of the chamber 2 shown in FIG. 3 is preferably 85 mm or smaller, more preferably, 30 mm or smaller, still further preferably, 25 mm or smaller.

Further, the height of the protruding portion 18c is set in accordance with the pressure in the chamber 2, the density of plasma to be generated, etc. For example, in a case where the pressure in the chamber 2 is 500 to 1100 Pa and the plasma density is 10⁹ to 10¹¹/cm³, the interval L between the top end of the protruding portion 18c and the chamber 2 shown in FIG. 3 is set to be further small, to 5 mm or smaller, preferably, 2.5 mm or smaller, still farther preferably, 0.8 mm or smaller. In a case where the interval L is so small as described just above, it is preferred that the dike 18 be structured to be able to lift up or down as shown in FIG. 5 and FIG. 6 as will be described later.

The dike 18 has a conductive member 18a formed of a conductor. According to the present embodiment, the dike 18 comprises the conductive member 18a and a covering member 18b. The conductive member 18a is constituted by a conductor. such as aluminum or the like, and grounded. The covering member 18b is constituted by an insulator such as ceramic or the like, which covers the conductive member 18a and electrically insulates between the conductive member 18a and the support table 15 and susceptor 16.

Since the conductive member 18a of the dike 18 is grounded as described above, the conductive member 18a (i.e., the dike 18) has a stable potential and a low impedance. Since this makes plasma be generated with, not the wall of the chamber 2, but the conductive member 18a serving as the opposite electrode, it is possible to securely prevent the plasma from spreading outside the dike 18.

The gas ejection device 3 is connected to the chamber 2 via the gas ejection tube 11. The gas ejection device 3 has a vacuum pump, and sets the pressure in the chamber 2 to a predetermined pressure (for example, 800 Pa) by ejecting gas in the chamber 2.

The process gas supply device 4 is connected to the chamber 2 via the gas supply tube 13, and supplies a process gas necessary for processing the wafer W into the chamber 2 at a predetermined flow rate (for example, 1000 sccm).

The first high-frequency power source 5 is connected to the susceptor 16 serving as the lower electrode via the first matching device 6, and applies a high-frequency wave of, for example, 13.56 to 100 MHz to the susceptor 16.

The second high-frequency power source 7 is connected to the showerhead 14 serving as the upper electrode via the second matching device 8, and applies a high-frequency wave of, for example, 0.8 to 13.56 MHz to the showerhead 14.

The control device 9 is constituted by a microcomputer or the like, and stores a program for applying a plasma process to the wafer W. The control device 9 controls the operation of the entire plasma processing apparatus 1 in accordance with the stored program, and performs a plasma CVD process on the wafer W placed in the chamber 2 to form a film of a predetermined kind on the wafer W.

Next, a multi-chamber system comprising the plasma processing apparatus 1 constituted as described above will be explained.

FIG. 4 is a diagram showing the structure of the multi-chamber system according to an embodiment of the present invention.

As shown in FIG. 4, the multi-chamber system 51 comprises a carry-in/carry-out chamber 52, a first transfer chamber 53, a load lock chamber 54, a second transfer chamber 55, and a plurality (four according to the present embodiment) of chambers 56 (56a to 56d).

The carry-in/carry-out chamber 52 is a room for carrying in or carrying out a process target, for example, a wafer (semiconductor wafer) to or from the multi-chamber system 51, and accommodates a plurality of cassettes 57 containing wafers. The carry-in/carry-out chamber 52 accommodates cassettes 57 that contain unprocessed wafers which are to be processed, and cassettes 57 that contain processed wafers.

The first transfer chamber 53 is a room that joins the carry-in/carry-out chamber 52 and the load lock chamber 54. A first transfer arm 58 is mounted in the first transfer chamber 53. The first transfer arm 58 transfers the wafer, and the wafer is carried in or carried out to or from the carry-in/carry-out chamber 52 or the load lock chamber 54.

The load lock chamber 54 is a room that joins the first transfer chamber 53 and the second transfer chamber 55 and carries in or carries out the wafer to or from the first transfer chamber 53 or the second transfer chamber 55.

The second transfer chamber 55 is a room that joins each chamber 56 and the load lock chamber 54. A second transfer arm 59 is mounted in the second transfer chamber 55. The second transfer arm 59 transfers the wafer, and the wafer is cared in or carried out to or from the load lock chamber 54 or each chamber 56.

Processing apparatuses suitable for the processes to be applied to the wafer is provided in the chambers 56 (56a to 56d). For example, according to the present embodiment, the plasma processing apparatus 1 according to the present invention is provided in the chamber 56a, and other processing apparatuses are provided in the chambers 56b to 56d.

The second transfer chamber 55 and each chamber 56 are maintained at a vacuum by an unillustrated vacuum control unit comprising a vacuum pump, a valve, etc. The load lock chamber 54 is structured to be able to be switched between a vacuum and a normal pressure by the vacuum control unit.

The first transfer chamber 53 and the load lock chamber 54 are connected via gate valves 60, and the load lock chamber 54 and the second transfer chamber 55 are connected via gate valves 61. The second transfer chamber 55 and each chamber 56 are connected via a gate valve 62.

A control unit 63 is connected to the first transfer arm 58, the second transfer arm 59, the gate valves 60, the gate valves 61, the gate valves 62, etc. The control unit 63 is constituted by a microcomputer or the like, and controls the operation of the entire multi-chamber system 51. For example, the control unit 63 controls the moves of the first transfer arm 58 and second transfer arm 59, and opening/closing of the gate valves 60, gate valves 61, and gate valves 62, so that the wafer may be transferred to a predetermined position. Thus, the wafer is transferred by the first transfer arm 58 from the cassette 57 accommodated in the carry-in/carry-out chamber 52 to the load lock chamber 54 via the first transfer chamber 53 and the gate valve 60. Then, the wafer in the load lock chamber 54 is transferred by the second transfer arm 59 to each chamber 56 via the gate valve 61, the second transfer chamber 55, and the gate valve 62.

Next, the operations of the plasma processing apparatus 1 and multi-chamber system 51 constituted as described above will be explained. The operations of the plasma processing apparatus 1 and multi-chamber system 51 to be described below are performed under the control of the control device 9 and the control unit 63.

First, the control unit 63 controls the first transfer arm 58 to take out an unprocessed wafer W from the cassette 57 containing unprocessed wafers W to be processed and transfer the wafer W to the load lock chamber 54 via the gate valve 60. Next, the control unit 63 controls the unillustrated vacuum control unit to vacuum the load lock chamber 54. Then, the control unit 63 controls the second transfer arm 59 to transfer the unprocessed wafer W in the load lock chamber 54 to the chamber 56a (plasma processing apparatus 1) via the gate valve 61 and the gate valve 62 (12) and mount the wafer W on the lifted up the lift pins 15a of the plasma processing apparatus 1.

When the unprocessed wafer W is mounted on the lift pins 15a, the control device 9 controls the unillustrated lifting mechanism to lower the lift pins 15a to mount the unprocessed wafer W on the susceptor 16.

Since the control device 9 supplies the refrigerant to the flow path 15b in the support table 15 by controlling the unillustrated refrigerant supply device, the temperature of the wafer W is set to a predetermined temperature when the wafer W is mounted on the susceptor 16. Further, the control device 9 controls the gas ejection device 3 to eject the gas in the chamber 2 to set the pressure in the chamber 2 to a predetermined pressure.

Next, the control device 9 controls the process gas supply device 4 to supply the process gas into the chamber 2 at a predetermined flow rate. Then, the control device 9 controls the second high-frequency power source 7 to apply a predetermined high-frequency voltage to the showerhead 14 serving as the upper electrode. Further, the control device 9 controls the first high-frequency power source 5 to apply a predetermined high-frequency voltage to the susceptor 16 serving as the lower electrode. Thus, plasma of the process gas supplied into the chamber 2 is generated and a predetermined film is formed on the wafer W by the generated plasma.

Here, since the dike 18 is provided around the support table 15 and susceptor 16 so as to surround the process area R, the generated plasma is confined in the process area R. Further, since the conductive member 18a of the dike 18 is grounded and the dike 18 thus has a stable potential and a low impedance so that not the wall of the chamber 2 but the conductive member 18a serves as the opposite electrode to generate the plasma, the plasma can be securely prevented from spreading outside the dike 18. Due to this, the plasma is concentrated in the process area R and the plasma process can thus be performed efficiently. Further, since the plasma can be prevented from spreading outside the process area R, it becomes easy to control the time for the process gas to stay in the process area R, the plasma intensity, the plasma distribution, etc. As a result, it becomes possible to control the quality, the film thickness, etc. of the film to be formed with a high accuracy, thereby to form a uniform film on the wafer W.

When the process of the wafer W is completed, the control device 9 controls the unillustrated lifting mechanism to lift up the lift pins 15a

When the lift pins 15a are lifted up, the control unit 63 controls the second transfer arm 59 to accommodate the wafer W on the lift pins l5a into the load lock chamber 54 via the gate valve 62 (12) and the gate valve 61. Then, the control unit 63 controls the first transfer arm 58 to transfer the wafer W in the load lock chamber 54 to the cassette 57 for accommodating processed wafers W via the gate valve 60.

As explained above, according to the present embodiment, since the dike 18 comprising the grounded conductive member 18a is provided so as to surround the process area R, the plasma is concentrated in the process area R and the plasma process can be performed efficiently. Further, it becomes easy to control the time for the process gas to stay in the process area R, the plasma intensity, the plasma distribution, etc. As a result, it becomes possible to control the quality, the film thickness, etc. of the film to be formed with a high accuracy, thereby to form a uniform film on the wafer W.

The present invention is not limited to the above-described embodiment, but can be modified or applied in various manners. Other embodiments applicable to the present invention will be explained below.

The above-described embodiment was explained by employing, as an example, a case where the dike 18 comprises the conductive member 18a and the covering member 18b. However, the dike 18 may not comprise the covering member 18b, but may comprise only the conductive member 18a. In this case, the conductive member 18a is formed of aluminum subjected to almite treatment (anodizing), or the like.

The above-described embodiment was explained by employing, as an example, a case where the dike 18 is placed on the bottom in the chamber 2. However, for example, as shown in FIG. 5 and FIG. 6, the dike 18 may be structured to be able to lift up or down. In FIG. 5 and FIG. 6, illustration of some components shown in FIG. 1 is omitted.

In the plasma processing apparatus 1 shown in FIG. 5, the support table 15 is connected to a support table lifting device 22 via a shaft 21. The support table lifting device 22 lifts up or down the support table 15, the susceptor 16, and the dike 18 wholly in the chamber 2 in accordance with the control of the control device 9. The atmospheres inside and outside the chamber 2 where the lifting portion of the support table 15 are separated by bellows 23 formed of, for example, stainless.

According to the above-described configuration, by the support table lifting device 22 lifting up the entire support table 15, the interval L between the dike 18 and the chamber 2 is kept sufficiently narrow while the wafer W is being processed. Due to this, plasma can be securely confined in the process area R. Further, in carrying in or carrying out the wafer W, by the support table lifting device 22 lifting down the entire support table 15, the wafer W can easily be carried in or carried out,

Further, in the plasma processing apparatus 1 shown in FIG. 6, the dike 18 is connected to a dike lifting device 24 via a shaft 21. The dike lifting device 24 lifts up or down only the dike 18 in the chamber 2 in accordance with the control of the control device 9. Also in this case, the atmospheres inside and outside the chamber 2 where the lifting portion of the dike 18 are separated by bellows 23 formed of, for example, stainless.

According to the above-described configuration, by the dike lifting device 24 lifting up the dike 18, the interval L between the dike 18 and the chamber 2 is kept sufficiently narrow while the wafer W is being processed. Due to this, plasma can be securely confined in the process area R. Further, in carrying in or carrying out the wafer W, by the dike lifting device 24 lifting down the dike 18, the wafer W can be easily carried in or carried out.

The above-described embodiment was explained by employing, as an example, a case where the present invention is applied to the plasma CVD apparatus. However, the present invention can be applied to any apparatus as long as it is a plasma processing apparatus for processing a process target, for example, a semiconductor wafer by using plasma. For example, the present invention can be applied to apparatuses for performing, for example, plasma etching, plasma oxidation, plasma ashing, etc. Further, the process target is not limited to a wafer W, but may be, for example, a glass substrate for a liquid crystal display device, etc.

The present invention is based on Japanese Patent Application No. 2003-403950 filed on Dec. 3, 2003 and including specification, claims, drawings and summary. The disclosure of the above Japanese Patent Application is incorporated herein by reference in its entirety.

### INDUSTRIAL APPLICABILITY

The present invention is useful for a plasma processing apparatus and a multi-chamber system having the same.

1. A plasma processing apparatus (1) for applying a plasma process to a process target (W), comprising:
a process chamber (2) for applying a plasma process to said process target (W);
a mounting table (16), provided in said process chamber (2), for mounting thereon said process target (W);
a process gas supply unit (4) for supplying a process gas for applying the plasma process to said process target (W) into said process chamber (2);
a plasma generation unit (5, 7) for generating plasma of the process gas supplied by said process gas supply unit (4) by applying a high-frequency voltage; and
a dike (18) for confining the plasma generated by said plasma generation unit (5, 7) in an area above said process target (W) mounted on said mounting table (16),
wherein said dike (18) comprises a conductive member (18a) formed of a conductor, and said conductive member (18a) is grounded.

2. The plasma processing apparatus (1) according to claim 1,
wherein said dike (18) comprises an insulating member (18b) which covers said conductive member (18a) and electrically insulates between said conductive member (18a) and said mounting table (16).

3. The plasma processing apparatus (1) according to claim 1,
wherein said dike (18) comprises a protruding portion (18c) which is formed to be higher than said process target (W) mounted on said mounting table (16), so as to surround the area above said process target (W).

4. The plasma processing apparatus (1) according to claim 1,
wherein an interval between a top end of said dike (18) and an inner wall of said process chamber (2) is 85 mm or smaller.

5. The plasma processing apparatus according to claim 1, further comprising a lifting unit (22, 24) for lifting up or down said dike (18) in said process chamber (2).

6. The plasma processing apparatus according to claim 1, further comprising a lifting unit (22) for lifting up or down said dike (18) and said mounting table (16) in said process chamber (2).

7. A multi-chamber system, wherein said plasma processing apparatus according to claim 1 is provided in at least one chamber.
